(19) United States
(12) Patent Application Publication
(10) Pub. No.: US 2025/0331368 A1
(43) Pub. Date: Oct. 23, 2025

(54) DISPLAY PANEL, METHOD FOR PRODUCING THE SAME, AND DISPLAY DEVICE

(71) Applicants: Mianyang HKC Optoelectronics Technology Co.,Ltd., MIANYANG (CN); HKC CORPORATION LIMITED, SHENZHEN (CN)

(72) Inventors: Zhisheng XIE, MIANYANG (CN); Yangling TANG, MIANYANG (CN); Qin LIANG, MIANYANG (CN); Xiufeng ZHOU, MIANYANG (CN); Haijiang YUAN, MIANYANG (CN)

(21) Appl. No.: 19/082,195

(22) Filed: Mar. 18, 2025

(30) Foreign Application Priority Data
Apr. 17, 2024 (CN) 202410468727.6

(51) Int. Cl. H10K 59/122; H10K 59/12; H10K 59/80; H10K 71/60

(52) U.S. Cl. CPC H10K 59/122; H10K 59/1201; H10K 59/80522; H10K 71/60

(57) ABSTRACT

A display panel, a method for producing a display panel, and a display device. The display panel includes a driving plate, a pixel defining layer, a cathode auxiliary layer, a first partition structure, a plurality of sub-pixels, and a second partition structure. The pixel defining layer protrudes from the driving plate and defines a pixel accommodating region. Each of the sub-pixels is at least partially disposed in the pixel accommodating region and includes an anode electrode, a first functional layer, a light-emitting layer, a second functional layer, and a cathode electrode. Cathode electrodes of two adjacent sub-pixels are electrically connected through the cathode auxiliary layer. The second partition structure is connected to the pixel defining layer and divides the first functional layer into a plurality of functional segments. Each of the functional segments is connected to one of or none of the cathode auxiliary layer and the anode electrode.

### CROSS REFERENCE TO RELATED APPLICATIONS

The present disclosure claims priority to Chinese patent application No. 202410468727.6 filed on Apr. 17, 2024, the entire contents of which are incorporated herein by reference.

### TECHNICAL FIELD

The present disclosure relates to the field of display devices, and in particular to a display panel, a method for producing a display panel, and a display device.

### BACKGROUND

An organic light-emitting display (OLED) is a current mainstream display technology. An OLED display panel includes an active OLED display panel (AMOLED) and a passive OLED display panel (PMOLED). At present, it is more and more common for the AMOLED to be produced by a maskless evaporation technology, in which an auxiliary cathode below a partition structure is conductive to a cathode, so as to supply power to the cathode.

However, in this case, a size of the auxiliary cathode may be limited by a size of the partition structure, and the auxiliary cathode may not be produced in a large width, resulting in that a hole injection material and a hole transmission material are continuously deposited on both an anode electrode and the auxiliary cathode, so that the anode electrode may be conductive to a cathode electrode, causing problems such as crosstalk short-circuit and etc.

### SUMMARY OF THE DISCLOSURE

In order to solve the problem, the present disclosure provides a display panel including a driving plate, a pixel defining layer, a cathode auxiliary layer, a first partition structure, a plurality of sub-pixels, and a second partition structure. The pixel defining layer is disposed on the driving plate. The pixel defining layer protrudes from the driving plate and defines a pixel accommodating region. The cathode auxiliary layer is disposed on a side of the pixel defining layer away from the driving plate. The first partition structure protrudes from a side of the cathode auxiliary layer away from the pixel defining layer. Each of the plurality of sub-pixels is at least partially disposed in the pixel accommodating region. Each of the sub-pixels includes an anode electrode, a first functional layer, a light-emitting layer, a second functional layer, and a cathode electrode, which are arranged in a stack. Two adjacent sub-pixels are separated from each other by the first partition structure. Cathode electrodes of the two adjacent sub-pixels are electrically connected through the cathode auxiliary layer. The second partition structure is connected to the pixel defining layer. The second partition structure is configured to divide the first functional layer into a plurality of functional segments separated from each other, to make each of the functional segments to be connected to one of or none of the cathode auxiliary layer and the anode electrode.

In order to solve the problem, the present disclosure also provides a method for producing a display panel. The method including steps of: forming a second partition structure on a side of a pixel defining layer; forming a first partition structure on a side of a cathode auxiliary layer away from a driving plate; and depositing a first functional layer, a light-emitting layer, a second functional layer, and a cathode electrode on a side of an anode electrode away from the driving plate, wherein the second partition structure is configured to divide the first functional layer into a plurality of functional segments separated from each other, to make each of the functional segments to be connected to one of or none of the cathode auxiliary layer and the anode electrode.

In order to solve the problem, the present disclosure further provides a display device including a display panel according to any one of embodiments above.

### BRIEF DESCRIPTION OF THE DRAWINGS

In order to more clearly illustrate the technical solutions in the embodiments of the present disclosure or the related art, the drawings needed to be used in the embodiments are briefly introduced below. Obviously, the drawings in the following description are only some embodiments of the present disclosure. For those skilled in the art, other drawings may also be obtained according to these drawings without any creative efforts.

FIG. 1 is a schematic structural view of a display device according to some embodiments of the present disclosure.

FIG. 2 is a first schematic structural view of a display panel according to some embodiments of the present disclosure.

FIG. 3 is a first schematic flow chart of a method for producing a display panel according to some embodiments of the present disclosure.

FIG. 4 is a second schematic flow chart of a method for producing a display panel according to some embodiments of the present disclosure.

FIG. 4a is a second schematic structural view of a display panel according to some embodiments of the present disclosure.

FIG. 4b is a third schematic structural view of a display panel as shown in FIG. 4a according to some embodiments of the present disclosure.

FIG. 4c is a fourth schematic structural view of a display panel as shown in FIG. 4a according to some embodiments of the present disclosure.

FIG. 4d is a fifth schematic structural view of a display panel as shown in FIG. 4a according to some embodiments of the present disclosure.

FIG. 5 is a third schematic flow chart of a method for producing a display panel according to some embodiments of the present disclosure.

FIG. 5a is a sixth schematic structural view of a display panel according to some embodiments of the present disclosure.

FIG. 5b is a seventh schematic structural view of a display panel as shown in FIG. 5a according to some embodiments of the present disclosure.

FIG. 5c is an eighth schematic structural view of a display panel as shown in FIG. 5a according to some embodiments of the present disclosure.

FIG. 5d is a ninth schematic structural view of a display panel as shown in FIG. 5a according to some embodiments of the present disclosure.

FIG. 5e is a tenth schematic structural view of a display panel as shown in FIG. 5a according to some embodiments of the present disclosure.

FIG. 6 is a fourth schematic flow chart of a method for producing a display panel according to some embodiments of the present disclosure.

FIG. 7 is a fifth schematic flow chart of a method for producing a display panel according to some embodiments of the present disclosure.

FIG. 7a is an eleventh schematic structural view of a display panel according to some embodiments of the present disclosure.

FIG. 8 is a sixth schematic flow chart of a method for producing a display panel according to some embodiments of the present disclosure.

FIG. 8a is a twelfth schematic structural view of a display panel according to some embodiments of the present disclosure.

FIG. 8b is a thirteenth schematic structural view of a display panel as shown in FIG. 8a according to some embodiments of the present disclosure.

FIG. 8c is a fourteenth schematic structural view of a display panel as shown in FIG. 8a according to some embodiments of the present disclosure.

FIG. 8d is a fifteenth schematic structural view of a display panel as shown in FIG. 8a according to some embodiments of the present disclosure.

FIG. 8e is a sixteenth schematic structural view of a display panel as shown in FIG. 8a according to some embodiments of the present disclosure.

FIG. 8f is a seventeenth schematic structural view of a display panel as shown in FIG. 8a according to some embodiments of the present disclosure.

Reference labels of the drawings: display device 1; display panel 2; driving plate 10; substrate 11; driving circuit layer 12; pixel defining layer 20; pixel accommodating region 21; first opening 22; cathode auxiliary layer 30; cathode auxiliary layer source layer 31; first partition structure 40; protruding portion 41; partition portion 42; sub-pixel 50; anode electrode 51; metal layer 510; first functional layer 52; first functional segment 521; second functional segment 522; light-emitting layer 53; second functional layer 54; cathode electrode 55; second partition structure 60; first sub-partition structure 61; second sub-partition structure 62; second partition structure source layer 600; first sub-partition structure source layer 610; second sub-partition structure source layer 620; encapsulating layer 700; filling layer 800; and cover plate 900.

### DETAILED DESCRIPTION

The technical solutions in the embodiments of the present disclosure are described in detail below in conjunction with the accompanying drawings. The following embodiments are only used to more clearly illustrate the technical solutions of the present disclosure, and therefore are only used as examples and cannot be used to limit the scope of protection of the present disclosure.

Unless otherwise defined, all technical and scientific terms used in the specification have the same meanings as generally understood by those skilled in the art of the present disclosure. The terms used in the specification are for the purpose of describing specific embodiments only and are not intended to limit the present disclosure. The terms “comprise” and “include”, as well as any variations thereof, in the description and claims of the present disclosure and in the description of the drawings above are intended to cover non-exclusive inclusion.

In the description of the embodiments of the present disclosure, the terms “first”, “second”, and etc. are merely used to distinguish different objects, and cannot be understood as indicating or implying relative importance or implicitly indicating the number, specific order or primary and secondary relationship of the indicated technical features. In the description of the embodiments of the present disclosure, the term “plurality” means more than two, unless otherwise specifically defined.

The term “embodiment” mentioned in the specification means that particular features, structures, or characteristics described in conjunction with the embodiments may be included in at least one embodiment of the present disclosure. This term appearing in various positions in the specification does not necessarily refer to a same embodiment, nor is it an independent or alternative embodiment mutually exclusive with other embodiments. Those skilled in the art explicitly or implicitly understand that the embodiments described in the specification may be combined with other embodiments.

In the description of the embodiments of the present disclosure, the term “and/or” is only represent an association relationship of associated objects, indicating that there may be three kinds of relationships. For example, A and/or B, which may indicate that there are three cases: A alone, A and B at the same time, and B alone. In addition, the character “/” in the specification generally indicates that a relationship between preceding and following objects is an “or”.

In the description of the embodiments of the present disclosure, the term “plurality” refers to more than two (including two). Similarly, the term “multiple groups” refers to more than two groups (including two groups), and the term “multiple pieces” refers to more than two pieces (including two pieces).

In the description of the embodiments of the present disclosure, the orientation or positional relationship indicated by technical terms such as “center”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise”, “counterclockwise”, “axial”, “radial”, “circumferential”, and etc. is based on the orientation or positional relationship shown in the drawings, is only for convenience of describing the embodiments of the present disclosure and simplifying the description, and does not indicate or imply that the device or element referred to must have a specific orientation, be constructed and operated in a specific orientation, and therefore cannot be construed as limiting embodiments of the present disclosure.

In the description of the embodiments of the present disclosure, unless otherwise specified and limited, technical terms such as “mount”, “connect”, “couple”, and “fix” shall be interpreted broadly. For example, the terms may refer to a fixed connection, a detachable connection, or an integrity. They may also refer to a mechanical connection or an electrical connection. They may further refer to a direct connection or an indirect connection through an intermediate medium. They may further refer to an internal communication between two elements or an interaction relationship between two elements. Those skilled in the art may understand the specific meanings of the terms above in the embodiments of the present disclosure according to specific circumstances.

An organic light-emitting display (OLED) is a current mainstream display technology. An OLED display panel includes an active OLED display panel (AMOLED) and a passive OLED display panel (PMOLED). At present, it is more and more common for the AMOLED to be produced by a maskless evaporation technology, in which an auxiliary cathode below a partition structure is conductive to a cathode, so as to supply power to the cathode.

However, in this case, a size of the auxiliary cathode may be limited by a size of the partition structure, and the auxiliary cathode may not be produced in a large width, resulting in that a hole injection material and a hole transmission material are continuously deposited on both an anode electrode and the auxiliary cathode, so that the anode electrode may be conductive to a cathode electrode, causing problems such as crosstalk, short-circuit, and etc.

The present disclosure provides a display device, which may include, but is not limited to, a mobile phone, a tablet computer, a laptop, a desktop computer, a terminal, an interactive display, a digital audio and video device, an Internet of Things device, and etc. The interactive display may include an interactive whiteboard, a digital advertisement interactive screen, a game interactive display, and etc. The Internet of Things device may include an intelligent home device, an intelligent wearable device, and etc. The display device may include a display panel, and the display device may provide a display interface and touch input by the display panel to achieve corresponding functions.

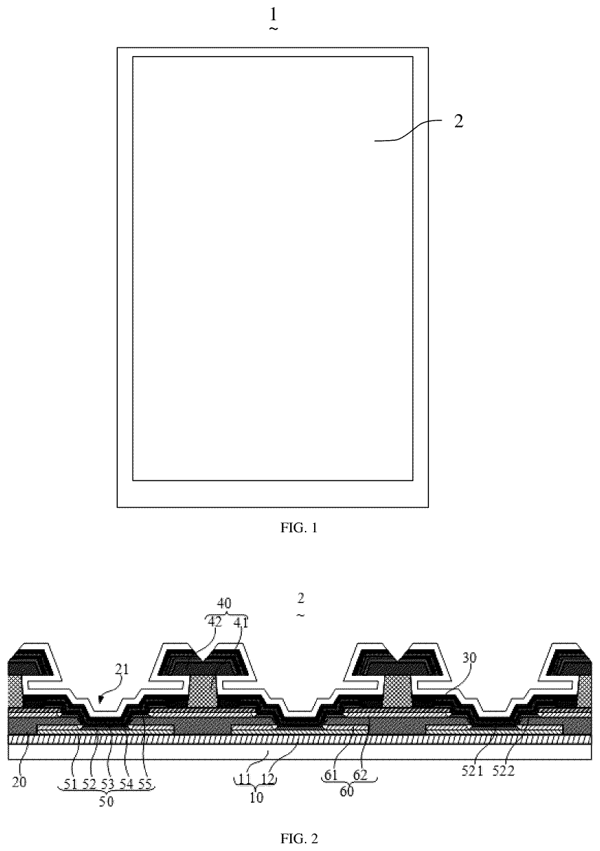

As shown in FIG. 1, FIG. 1 is a schematic structural view of a display device according to some embodiments of the present disclosure.

The display device 1 may be an ordinary mobile phone, a functional mobile phone, or a smart phone. The smart phone may be a flat screen mobile phone, a curved screen mobile phone, or a foldable mobile phone. The display device 1 may include a display panel 2, and the display panel 2 may be arranged at the head, middle, or tail of the display device 1. The display panel 2 may be configured to display information of the display device 1. For example, the display panel 2 may serve as a visual information display portion of the display device 1. The display panel 2 may also be serve as a touch information input portion and configured to facilitate the user to operate the display device 1 by touching the display panel 2. For example, the display panel 2 is configured to display and input requirements during interface navigation and function switching of the display device 1.

As shown in FIG. 2, FIG. 2 is a first schematic structural view of a display panel according to some embodiments of the present disclosure.

The present disclosure provides a display panel 2 including a driving plate 10, a pixel defining layer 20, a cathode auxiliary layer 30, a first partition structure 40, a plurality of sub-pixels 50, and a second partition structure 60. The pixel defining layer 20 is disposed on the driving plate 10. The pixel defining layer 20 protrudes from the driving plate 10 and defines a pixel accommodating region 21. The cathode auxiliary layer 30 is disposed on a side of the pixel defining layer 20 away from the driving plate 10. The first partition structure 40 protrudes from a side of the cathode auxiliary layer 30 away from the pixel defining layer 20. Each of the plurality of sub-pixels 50 is at least partially disposed in the pixel accommodating region 21. Each of the sub-pixels 50 includes an anode electrode 51, a first functional layer 52, a light-emitting layer 53, a second functional layer 54, and a cathode electrode 55, which are arranged in a stack. Two adjacent sub-pixels 50 are separated from each other by the first partition structure 40. Two cathode electrodes 55 of the two adjacent sub-pixels 50 are electrically connected through the cathode auxiliary layer 30. The second partition structure 60 is connected to the pixel defining layer 20. The second partition structure 60 is configured to divide the first functional layer 52 into a plurality of functional segments separated from each other, to make each of the functional segments to be connected to one of or none of the cathode auxiliary layer 30 and the anode electrode 51. The driving plate 10 may include a substrate 11 and a driving circuit layer 12. The substrate 11 may be a glass substrate or a flexible substrate. The material of the flexible substrate is polyimide (PI). The driving circuit layer 12 may be a thin film transistor (TFT) circuit layer for driving the light-emitting layer 53 of the OLED. The TFT circuit layer includes a plurality of driving circuit units arranged in an array. Each of the driving circuit units may include a TFT element and a capacitor. Each of the driving circuit units corresponds to one anode electrode 51 and one light-emitting layer 53. The TFT element is a low temperature poly-silicon (LTPS) type or a metal-oxide semiconductor (MOS) type, such as a metal-oxide semiconductor type of indium gallium zinc oxide (IGZO).

The pixel defining layer 20 is disposed on the driving plate 10 and protrudes from the driving plate 10 to define the pixel accommodating region 21. The pixel defining layer 20 may limit positions of the sub-pixels 50 by the pixel accommodating region 21, to make the sub-pixels 50 to be disposed at appropriate positions. The material of the pixel defining layer 20 may be one of an organic material, an organic material provided with an inorganic coating thereon, or an inorganic material. The organic material of the pixel defining layer 20 includes, but is not limited to, polyimide. The inorganic material of the pixel defining layer 20 includes, but is not limited to, silicon oxide (SiO₂), silicon nitride (Si₃N₄), silicon oxynitride (Si₂N₂O), magnesium fluoride (MgF₂), or a combination thereof.

The cathode auxiliary layer 30 is disposed on the side of the pixel defining layer 20 away from the driving plate 10. An end of the cathode electrode 55 is in contact with the cathode auxiliary layer 30, such that the two cathode electrodes 55 of the two adjacent sub-pixels 50 are enabled to be conducted through the cathode auxiliary layer 30. The material of the cathode auxiliary layer 30 includes, but is not limited to, chromium, titanium, gold, silver, copper, aluminum, indium tin oxide (ITO), a combination thereof, or other suitable conductive materials.

The first partition structure 40 protrudes from the side of the cathode auxiliary layer 30 away from the pixel defining layer 20. In some embodiments, the first partition structure 40 may be in contact with the cathode auxiliary layer 30.

Each of the plurality of sub-pixels 50 is at least partially disposed in the pixel accommodating region 21. Each of the sub-pixels 50 includes the anode electrode 51, the first functional layer 52, the light-emitting layer 53, the second functional layer 54, and the cathode electrode 55, which are arranged in a stack. The two adjacent sub-pixels 50 are separated from each other by the first partition structure 40. The two cathode electrodes 55 of the two adjacent sub-pixels 50 are electrically connected through the cathode auxiliary layer 30. The anode electrode 51 is disposed between the pixel defining layer 20 and the driving plate 10. In some embodiments, the anode electrode 51 may be disposed on a surface of the driving circuit layer 12 away from the substrate 11. For example, anode electrodes 51 of the plurality of sub-pixels 50 are arranged in an array, and each of the anode electrodes 51 corresponds to and is electrically connected to each of the driving circuit units of the driving circuit layer 12 one by one. The material of the anode electrode 51 includes, but is not limited to, chromium, titanium, gold, silver, copper, aluminum, ITO, a combination thereof, or other suitable conductive materials.

The first functional layer 52 may include one or more of a hole injection layer (HIL) and a hole transfer layer (HTL).

The light-emitting layer 53 is configured to emit red light, blue light, or green light when powered on.

The second functional layer 54 may include one or more of an electron transfer layer (ETL) and an electron injection layer (EIL).

The second partition structure 60 is connected to the pixel defining layer 20 and is configured to divide the first functional layer 52 into the plurality of functional segments separated from each other, to make each of the functional segments to be connected to one of or none of the cathode auxiliary layer 30 and the anode electrode 51. The second partition structure 60 may be located on a side of the pixel defining layer 20 close to the driving plate 10, or may be located on the side of the pixel defining layer 20 away from the driving plate 10. The second partition structure 60 may partition the first functional layer 52 when the first functional layer 52 is deposited and formed, thereby dividing the first functional layer 52 into the plurality of functional segments separated from each other, to make each of the functional segments to be connected to one of or none of the cathode auxiliary layer 30 and the anode electrode 51. It can be understood that each of the functional segments may be connected to the cathode auxiliary layer 30 and separated from the anode electrode 51, or may be connected to the anode electrode 51 and separated from the cathode auxiliary layer 30, or may be separated from both the anode electrode 51 and the cathode auxiliary layer 30. When the first functional layer 52 is deposited and formed, the first functional layer 52 is divided into the plurality of functional segments separated from each other by the second partition structure 60. As a result, the plurality of functional segments do not conduct electricity continuously. A functional segment connected to the anode electrode 51 cannot define a conduction path with a functional segment connected to the cathode auxiliary layer 30, thereby greatly reducing a risk of crosstalk short-circuit between the cathode electrode 55 and the anode electrode 51 via the cathode auxiliary layer 30 and the first functional layer 52 due to electrical conduction between the cathode auxiliary layer 30 and the anode electrode 51 via the first functional layer 52.

In some embodiments, a length of an orthographic projection of the first partition structure 40 projected on the driving plate 10 is smaller than a length of an orthographic projection of the cathode auxiliary layer 30 projected on the driving plate 10 in a separation direction of the two adjacent sub-pixels 50. For example, a red sub-pixel and a blue sub-pixel adjacent to the red sub-pixel are separated from each other by the first partition structure 40, and a length of the orthographic projection of the first partition structure 40 projected on the driving plate 10 in a separation direction of the red sub-pixel and the blue sub-pixel is smaller than a length of the orthographic projection of the cathode auxiliary layer 30 projected on the driving plate 10 in the separation direction of the red sub-pixel and the blue sub-pixel. It can be understand that although the length of the orthographic projection of the first partition structure 40 projected on the driving plate 10 is smaller than the length of the orthographic projection of the cathode auxiliary layer 30 projected on the driving plate 10, when depositing the material of the first functional layer 52, at least partial first functional layer 52 is deposited and connected to the cathode auxiliary layer 30 which is not covered by the first partition structure 40. However, because the first functional layer 52 is divided by the second partition structure 60 into the plurality of functional segments separated from each other, the first functional layer 52 deposited on the cathode auxiliary layer 30 is one of the plurality of functional segments, which is connected to the cathode auxiliary layer 30 and separated from the anode electrode 51. Therefore, the fact that the length of the orthographic projection of the first partition structure 40 projected on the driving plate 10 is smaller than the length of the orthographic projection of the cathode auxiliary layer 30 projected on the driving plate 10 may not cause crosstalk short-circuit between the cathode electrode 55 and the anode electrode 51 through the cathode auxiliary layer 30. At the same time, a contact area between the cathode electrode 55 and the cathode auxiliary layer 30 and a wiring area of the cathode auxiliary layer 30 may be increased, thereby making a connection between the cathode electrode 55 and the cathode auxiliary layer 30 more stable, reducing a resistance of the cathode auxiliary layer 30, improving an adhesion ability of the cathode auxiliary layer 30, and further improving a display performance of the display panel 2.

In some embodiments, the second partition structure 60 includes a first sub-partition structure 61 disposed on a side of the anode electrode 51 away from the driving plate 10. The pixel defining layer 20 is covered the first sub-partition structure 61. The material of the first sub-partition structure 61 may include, but is not limited to, silver, molybdenum, titanium, aluminum, tungsten, or alloys thereof. The material of the first sub-partition structure 61 may be partially the same as or completely different from that of the anode electrode 51. For example, the material of the anode electrode 51 may be three-layer material of ITO/Ag/ITO, and the material of the first sub-partition structure 61 may be aluminum or molybdenum aluminum alloy. The first sub-partition structure 61 is disposed on the side of the anode electrode 51 away from the driving plate 10, and the pixel defining layer 20 is covered the first sub-partition structure 61. For example, the first sub-partition structure 61 may be located between the anode electrode 51 and the pixel defining layer 20. When depositing the material of the first functional layer 52, partial first functional layer 52 is deposited on a surface of the anode electrode 51 away from the driving plate 10, and partial first functional layer 52 is deposited on a surface of the pixel defining layer 20 away from the driving plate 10. First functional layers 52 deposited on the surface of the anode electrode 51 away from the driving plate 10 and the surface of the pixel defining layer 20 away from the driving plate 10 are partitioned by the first sub-partition structure 61 at the anode electrode 51, thus being separated from each other, reducing the electrical conduction between the cathode auxiliary layer 30 and the anode electrode 51 through the first functional layer 52, and further reducing the risk of crosstalk short-circuit between the cathode electrode 55 and the anode electrode 51.

In some embodiments, the plurality of functional segments include a first functional segment 521. The first functional segment 521 is located on a surface of the anode electrode 51 away from the driving plate 10. A thickness of the first functional segment 521 is smaller than a thickness of the first sub-partition structure 61. Since the thickness of the first functional segment 521 is smaller than the thickness of the first sub-partition structure 61, and the pixel defining layer 20 is covered the first sub-partition structure 61, it is difficult for the first functional segment 521 to be overlapped on the surface of the pixel defining layer 20 away from the driving plate 10 by a sidewall of the first functional segment 521. Thus, the first functional segment 521 may be sufficiently separated from other functional segments deposited on the side of the pixel defining layer 20 away from the driving plate 10, further reducing the risk of crosstalk short-circuit caused by electrical conduction between the cathode electrode 55 and the anode electrode 51 through the first functional layer 52.

In some embodiments, the second partition structure 60 includes a second sub-partition structure 62. The second sub-partition structure 62 is disposed on the side of the pixel defining layer 20 away from the driving plate 10. The cathode auxiliary layer 30 is covered the second sub-partition structure 62. The material of the second sub-partition structure 62 may be different from the material of the cathode auxiliary layer 30. For example, a reaction rate between the material of the second sub-partition structure 62 and an etchant may be faster than a reaction rate between the material of the cathode auxiliary layer 30 and the etchant. For example, when the material of the cathode auxiliary layer 30 is titanium, the material of the second sub-partition structure 62 may be molybdenum. The second sub-partition structure 62 is disposed on the side of the pixel defining layer 20 away from the driving plate 10, and the cathode auxiliary layer 30 is covered the second sub-partition structure 62. For example, the second sub-partition structure 62 may be located between the cathode auxiliary layer 30 and the pixel defining layer 20. Therefore, when depositing the material of the first functional layer 52, partial first functional layer 52 is deposited on a surface of the cathode auxiliary layer 30 away from the pixel defining layer 20, and partial first functional layer 52 is deposited on the surface of the pixel defining layer 20 away from the driving plate 10. First functional layers 52 deposited on the surface of the cathode auxiliary layer 30 away from the pixel defining layer 20 and the surface of the pixel defining layer 20 away from the driving plate 10 are partitioned by the second sub-partition structure 62 at the cathode auxiliary layer 30, thus being separated from each other, reducing the electrical conduction between the cathode auxiliary layer 30 and the anode electrode 51 through the first functional layer 52, and further reducing the risk of crosstalk short-circuit between the cathode electrode 55 and the anode electrode 51.

In some embodiments, the plurality of functional segments include a second functional segment 522. The second functional segment 522 is located on the surface of the pixel defining layer 20 away from the driving plate 10. A thickness of the second functional segment 522 is smaller than a thickness of the second sub-partition structure 62. Since the thickness of the second functional segment 522 is smaller than the thickness of the second sub-partition structure 62, and the cathode auxiliary layer 30 is covered the second sub-partition structure 62, it is difficult for the second functional segment 522 to be overlapped on a surface of the cathode auxiliary layer 30 away from the pixel defining layer 20 by a sidewall of the second functional segment 522. Thus, the second functional segment 522 may be sufficiently separated from other functional segments deposited on a side of the cathode auxiliary layer 30 away from the pixel defining layer 20, further reducing the risk of crosstalk short-circuit caused by electrical conduction between the cathode electrode 55 and the anode electrode 51 through the first functional layer 52.

In some embodiments, the second partition structure 60 includes the first sub-partition structure 61 and the second sub-partition structure 62. The first sub-partition structure 61 is disposed on the side of the anode electrode 51 away from the driving plate 10, and the pixel defining layer 20 is covered the first sub-partition structure 61. The second sub-partition structure 62 is disposed on the side of the pixel defining layer 20 away from the driving plate 10, and the cathode auxiliary layer 30 is covered the second sub-partition structure 62. The second partition structure 60 may include both the first sub-partition structure 61 and the second sub-partition structure 62. When depositing the material of the first functional layer 52, partial first functional layer 52 is deposited on the surface of the anode electrode 51 away from the driving plate 10, partial first functional layer 52 is deposited on the surface of the pixel defining layer 20 away from the driving plate 10, and partial first functional layer 52 is deposited on the surface of the cathode auxiliary layer 30 away from the pixel defining layer 20. First functional layers 52 deposited on the surface of the anode electrode 51 away from the driving plate 10, the surface of the pixel defining layer 20 away from the driving plate 10, and the surface of the cathode auxiliary layer 30 away from the pixel defining layer 20 are partitioned by the first sub-separation structure 61 at the anode electrode 51 and the second sub-separation structure 62 at the cathode auxiliary layer 30, respectively, thus being separated from each other, greatly reducing the electrical conduction between the cathode auxiliary layer 30 and the anode electrode 51 through the first functional layer 52, and further reducing the risk of crosstalk short-circuit of the anode electrode 51.

In some embodiments, the first partition structure 40 includes a protruding portion 41 and a partition portion 42. The protruding portion 41 is protrudingly disposed on the side of the cathode auxiliary layer 30 away from the pixel defining layer 20. The partition portion 42 is disposed on a side of the protruding portion 41 away from the cathode auxiliary layer 30. In the separation direction of the two adjacent sub-pixels 50, a length of an orthographic projection of the partition portion 42 projected on the driving plate 10 is greater than a length of an orthographic projection of the protruding portion 41 projected on the driving plate 10, and the length of the orthographic projection of the partition portion 42 projected on the driving plate 10 is smaller than a length of an orthographic projection of the cathode auxiliary layer 30 projected on the driving plate 10. The material of the protruding portion 41 may be a conductive material or a non-conductive material, which is determined according to actual requirements. The material of the partition portion 42 may be one of a non-conductive organic material and a non-conductive inorganic material. The non-conductive inorganic material includes, but is not limited to, an inorganic silicon-containing material. The silicon-containing material includes an oxide or a nitride of silicon or a combination thereof. The non-conductive organic material includes a negative photosensitive organic material. The negative photosensitive organic material includes, but is not limited to, a negative photoresist. The partition portion 42 may partition the first functional layer 52, the light-emitting layer 53, the second functional layer 54, and the cathode electrode 55 between the two adjacent sub-pixels 50 during evaporation deposition, thereby reducing the use of a metal mask, simplifying the manufacturing process, and saving costs. In the separation direction of the two adjacent sub-pixels 50, the length of the orthographic projection of the partition portion 42 projected on the driving plate 10 is greater than the length of the orthographic projection of the protruding portion 41 projected on the driving plate 10, and the length of the orthographic projection of the partition portion 42 projected on the driving plate 10 is smaller than the length of the orthographic projection of the cathode auxiliary layer 30 projected on the driving plate 10. Thus, the partition portion 42 may better partition the first functional layer 52, the light-emitting layer 53, the second functional layer 54, and the cathode electrode 55 between the two adjacent sub-pixels 50, thereby making a contact area between the cathode electrode 55 of each of the sub-pixels 50 and the cathode auxiliary layer 30 to be increased, improving the stability of the connection between the cathode electrode 55 and the cathode auxiliary layer 30, and increasing the wiring area of the cathode auxiliary layer 30. Therefore, the resistance of the cathode auxiliary layer 30 is reduced, the adhesion ability of the cathode auxiliary layer 30 is improved, and the display performance of the display panel 2 is improved.

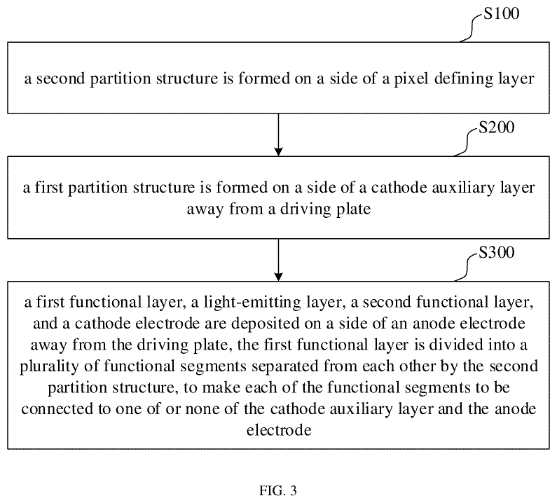

As shown in FIG. 3, FIG. 3 is a first schematic flow chart of a method for producing a display panel according to some embodiments of the present disclosure.

The present disclosure also provides a method for producing a display panel, which may be configured to produce the display panel 2 mentioned above. The method for producing the display panel may include operations executed by the following blocks.

At block S100, a second partition structure 60 is formed on a side of a pixel defining layer 20.

At block S200, a first partition structure 40 is formed on a side of a cathode auxiliary layer 30 away from a driving plate 10.

At block S300, a first functional layer 52, a light-emitting layer 53, a second functional layer 54, and a cathode electrode 55 are deposited on a side of an anode electrode 51 away from the driving plate 10. The first functional layer 52 is divided into a plurality of functional segments separated from each other by the second partition structure 60, to make each of the functional segments to be connected to one of or none of the cathode auxiliary layer 30 and the anode electrode 51.

In some embodiments, the second partition structure 60 is formed on the side of the pixel defining layer 20, the first partition structure 40 is formed on the side of the cathode auxiliary layer 30 away from the driving plate 10, and the first functional layer 52, the light-emitting layer 53, the second functional layer 54, and the cathode electrode 55 are deposited on the side of the anode electrode 51 away from the driving plate 10. In this way, the second partition structure 60 divides the first functional layer 52 into the plurality of functional segments separated from each other, to make each of the functional segments to be connected to one of or none of the cathode auxiliary layer 30 and the anode electrode 51, thereby reducing the electrical conduction between the cathode auxiliary layer 30 and the anode electrode 51 through the first functional layer 52, and further reducing the risk of crosstalk short-circuit between the cathode electrode 55 and the anode electrode 51.

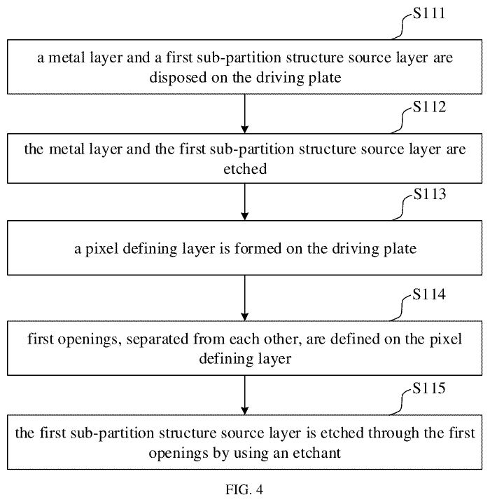

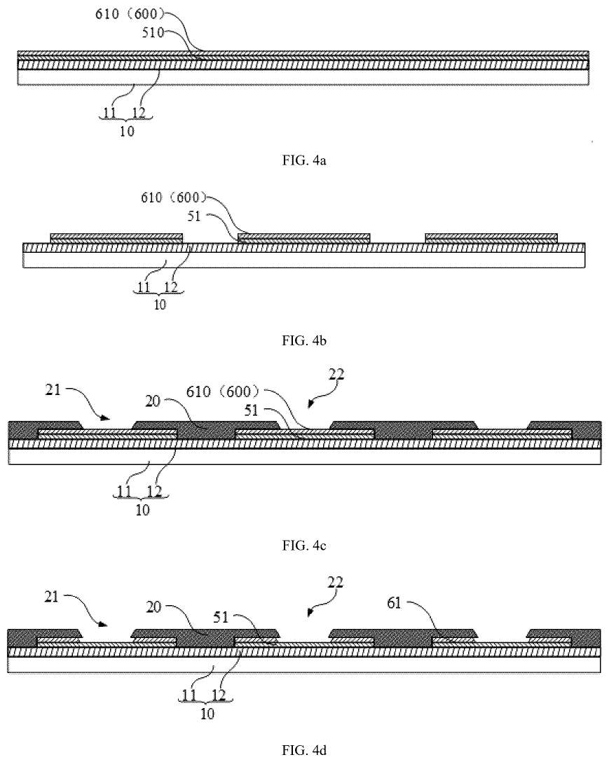

As shown in FIG. 4 to FIG. 4d, FIG. 4 is a second schematic flow chart of a method for producing a display panel according to some embodiments of the present disclosure, FIG. 4a is a second schematic structural view of a display panel according to some embodiments of the present disclosure, FIG. 4b is a third schematic structural view of a display panel as shown in FIG. 4a according to some embodiments of the present disclosure, FIG. 4c is a fourth schematic structural view of a display panel as shown in FIG. 4a according to some embodiments of the present disclosure, and FIG. 4d is a fifth schematic structural view of a display panel as shown in FIG. 4a according to some embodiments of the present disclosure.

In some embodiments, the block of a second partition structure 60 being formed on a side of a pixel defining layer 20 may include the following operations.

At block S111, a metal layer 510 and a first sub-partition structure source layer 610 are disposed on the driving plate 10.

In some embodiments, the driving plate 10 is acquired. The driving plate 10 includes a substrate 11 and a drive circuit layer 12.

The substrate 11 may be a glass substrate or a flexible substrate. The material of the flexible substrate is polyimide (PI). The driving circuit layer 12 may be a TFT circuit layer for driving the light-emitting layer 53 of the OLED. The TFT circuit layer includes a plurality of TFT elements arranged in an array. Each of the TFT elements corresponds to the light-emitting layer 53 one by one. The TFT element is a low temperature poly-silicon (LTPS) type or a metal-oxide semiconductor (MOS) type, such as a metal-oxide semiconductor type of indium gallium zinc oxide (IGZO).

The metal layer 510 is covered a surface of the drive circuit layer 12 away from the substrate 11. The material of the metal layer 510 include, but is not limited to, chromium, titanium, gold, silver, copper, aluminum, ITO, a combination thereof, or other suitable conductive materials.

A side of the metal layer 510 away from the driving circuit layer 12 is covered with the first sub-partition structure source layer 610.

At block S112, the metal layer 510 and the first sub-partition structure source layer 610 are etched.

In some embodiments, the metal layer 510 and the first sub-partition structure source layer 610 are patterned by means of wet etching or dry etching to obtain anode electrodes 51 separated from each other and the first sub-partition structure source layer 610 etched for the first time. The dry etching includes laser etching or plasma etching. The wet etching includes chemical etching.

At block S113, a pixel defining layer 20 is formed on the driving plate 10.

In some embodiments, the pixel defining layer 20 is formed on a side of the first sub-partition structure source layer 610 away from the driving plate 10. The material of the pixel defining layer 20 may be one of an organic material, an organic material provided with an inorganic coating thereon, or an inorganic material. The organic material of the pixel defining layer 20 includes, but is not limited to, polyimide. The inorganic material of the pixel defining layer 20 includes, but is not limited to, SiO₂, Si₃N₄, Si₂N₂O, MgF₂, or a combination thereof.

At block S114, first openings 22, separated from each other, are defined on the pixel defining layer 20.

In some embodiments, a mask is covered on the surface of the pixel defining layer 20 away from the driving plate 10. The first openings 22, separated from each other, are defined on the pixel defining layer 20 by means of dry etching, to make the first sub-partition structure source layer 610 to be exposed through the first openings 22. The mask is removed. The pixel defining layer 20 defines the anode electrodes 51 to form sub-pixels 50.

At block S115, the first sub-partition structure source layer 610 is etched through the first openings 22 by using an etchant.

In some embodiments, the etchant may react with the first sub-partition structure source layer 610, but cannot react with the anode electrodes 51. The first sub-partition structure source layer 610 not exposed by the first openings 22 defines first sub-partition structures 61 under the protection of the pixel defining layer 20.

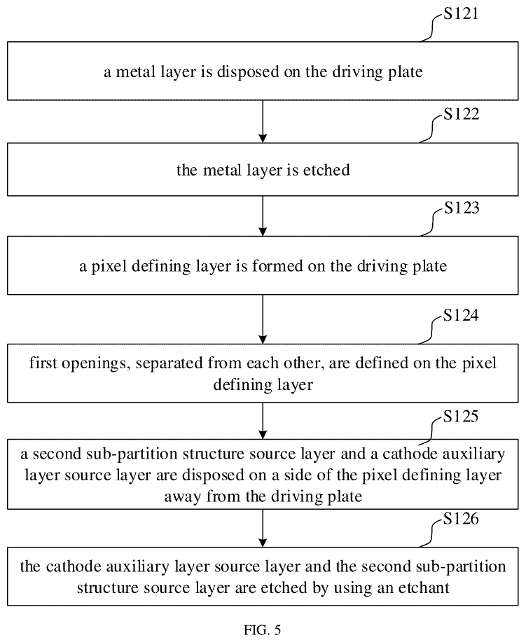

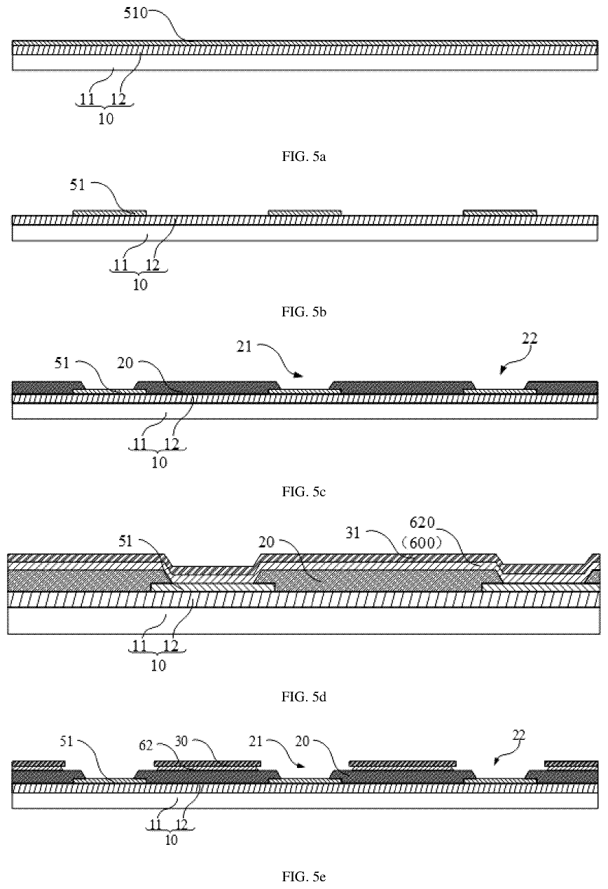

As shown in FIG. 5 to FIG. 5e, FIG. 5 is a third schematic flow chart of a method for producing a display panel according to some embodiments of the present disclosure, FIG. 5a is a sixth schematic structural view of a display panel according to some embodiments of the present disclosure, FIG. 5b is a seventh schematic structural view of a display panel as shown in FIG. 5a according to some embodiments of the present disclosure, FIG. 5c is an eighth schematic structural view of a display panel as shown in FIG. 5a according to some embodiments of the present disclosure, FIG. 5d is a ninth schematic structural view of a display panel as shown in FIG. 5a according to some embodiments of the present disclosure, and FIG. 5e is a tenth schematic structural view of a display panel as shown in FIG. 5a according to some embodiments of the present disclosure.

In some embodiments, the block of a second partition structure 60 being formed on a side of a pixel defining layer 20 may include the following operations.

At block S121, a metal layer 510 is disposed on the driving plate 10.

The operation of block S121 may be similar to the operation of block S111, and is not repeated here.

At block S122, the metal layer 510 is etched.

The operation of block S122 may be similar to the operation of block S112, and is not repeated here.

At block S123, a pixel defining layer 20 is formed on the driving plate 10.

The operation of block S123 may be similar to the operation of block S113, and is not repeated here.

At block S124, first openings 22, separated from each other, are defined on the pixel defining layer 20.

The operation of block S124 may be similar to the operation of block S114, and is not repeated here.

At block S125, a second sub-partition structure source layer 620 and a cathode auxiliary layer source layer 31 are disposed on a side of the pixel defining layer 20 away from the driving plate 10.

In some embodiments, the side of the pixel defining layer 20 away from the driving plate 10 is covered with the second sub-partition structure source layer 620. A side of the second sub-partition structure source layer 620 away from the pixel defining layer 20 is covered with the cathode auxiliary layer source layer 31.

At block S126, the cathode auxiliary layer source layer 31 and the second sub-partition structure source layer 620 are etched by using an etchant.

In some embodiments, the cathode auxiliary layer source layer 31 and the second sub-partition structure source layer 620 are etched by means of wet etching. The reaction speed of the etchant with the second sub-partition structure source layer 620 is faster than the reaction speed of the etchant with the cathode auxiliary layer source layer 31, thereby forming second sub-partition structures 62.

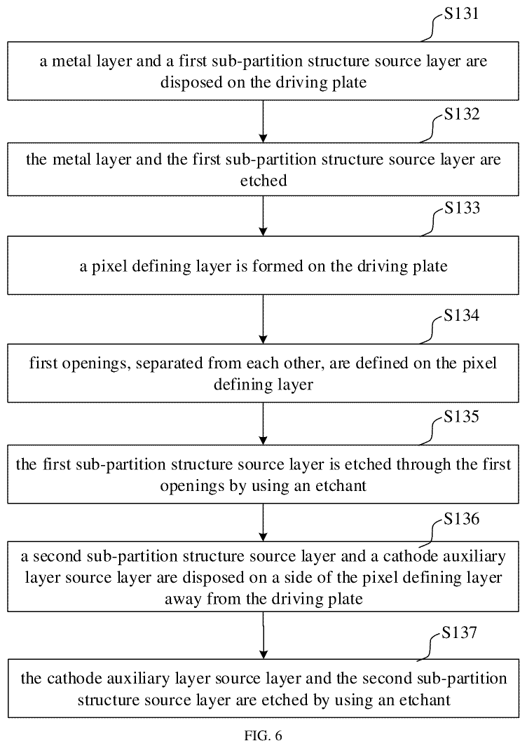

As shown in FIG. 6, FIG. 6 is a fourth schematic flow chart of a method for producing a display panel according to some embodiments of the present disclosure.

In some embodiments, the block of a second partition structure 60 being formed on a side of a pixel defining layer 20 may include the following operations.

At block S131, a metal layer 510 and a first sub-partition structure source layer 610 are disposed on the driving plate 10.

The operation of block S131 may be similar to the operation of block S111, and is not repeated here.

At block S132, the metal layer 510 and the first sub-partition structure source layer 610 are etched.

The operation of block S132 may be similar to the operation of block S112, and is not repeated here.

At block S133, a pixel defining layer 20 is formed on the driving plate 10.

The operation of block S133 may be similar to the operation of block S113, and is not repeated here.

At block S134, first openings 22, separated from each other, are defined on the pixel defining layer 20.

The operation of block S134 may be similar to the operation of block S114, and is not repeated here.

At block S135: the first sub-partition structure source layer 610 is etched through the first openings 22 by using an etchant.

The operation of block S135 may be similar to the operation of block S115, and is not repeated here.

At block S136, a second sub-partition structure source layer 620 and a cathode auxiliary layer source layer 31 are disposed on a side of the pixel defining layer 20 away from the driving plate 10.

The operation of block S136 may be similar to the operation of block S125, and is not repeated here.

At block S137, the cathode auxiliary layer source layer 31 and the second sub-partition structure source layer 620 are etched by using an etchant.

The operation of block S137 may be similar to the operation of block S126, and is not repeated here.

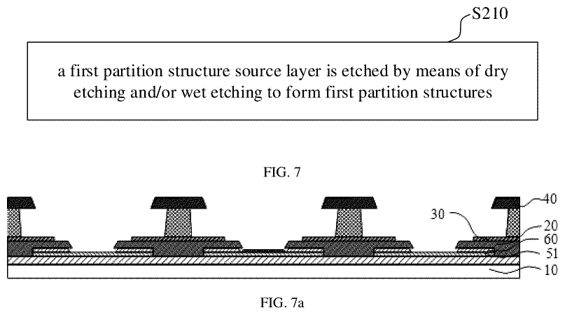

As shown in FIG. 7 and FIG. 7a, FIG. 7 is a fifth schematic flow chart of a method for producing a display panel according to some embodiments of the present disclosure, and FIG. 7a is an eleventh schematic structural view of a display panel according to some embodiments of the present disclosure.

In some embodiments, the block of a first partition structure 40 being formed on a side of a cathode auxiliary layer 30 away from a driving plate 10 may include the following operations.

At block S210, a first partition structure source layer is etched by means of dry etching and/or wet etching to form first partition structures.

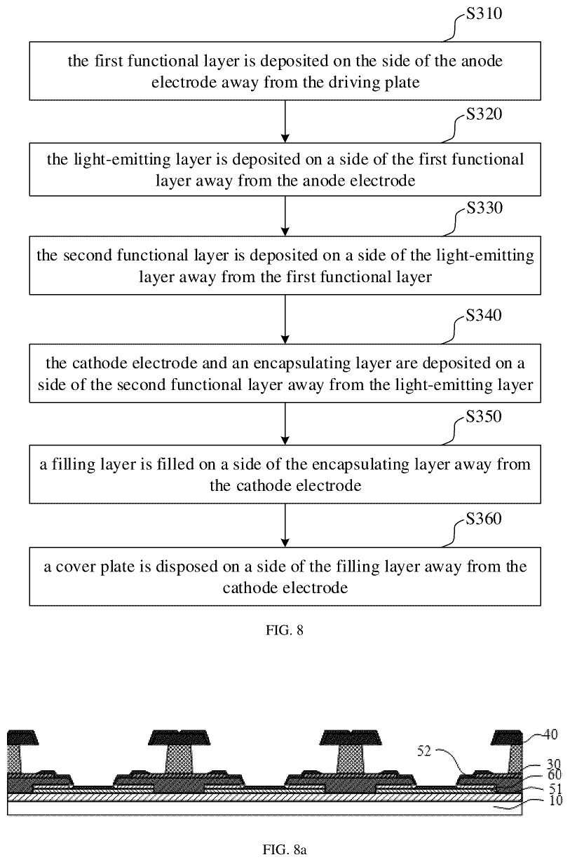

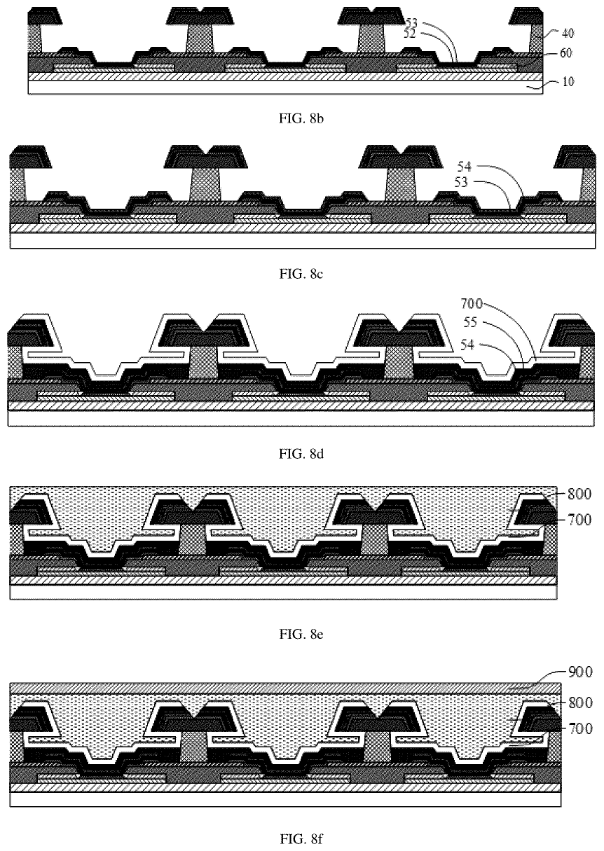

As shown in FIG. 8 to FIG. 8f, FIG. 8 is a sixth schematic flow chart of a method for producing a display panel according to some embodiments of the present disclosure, FIG. 8a is a twelfth schematic structural view of a display panel according to some embodiments of the present disclosure, FIG. 8b is a thirteenth schematic structural view of a display panel as shown in FIG. 8a according to some embodiments of the present disclosure, FIG. 8c is a fourteenth schematic structural view of a display panel as shown in FIG. 8a according to some embodiments of the present disclosure, FIG. 8d is a fifteenth schematic structural view of a display panel as shown in FIG. 8a according to some embodiments of the present disclosure, FIG. 8e is a sixteenth schematic structural view of a display panel as shown in FIG. 8a according to some embodiments of the present disclosure, and FIG. 8f is a seventeenth schematic structural view of a display panel as shown in FIG. 8a according to some embodiments of the present disclosure.

In some embodiments, the block of a first functional layer 52, a light-emitting layer 53, a second functional layer 54, and a cathode electrode 55 being deposited on a side of an anode electrode 51 away from the driving plate 10, and the first functional layer 52 being divided into a plurality of functional segments separated from each other by the second partition structure 60, to make each of the functional segments to be connected to one of or none of the cathode auxiliary layer 30 and the anode electrode 51 may include the following operations.

At block S310, the first functional layer 52 is deposited on the side of the anode electrode 51 away from the driving plate 10.

At block S320, the light-emitting layer 53 is deposited on a side of the first functional layer 52 away from the anode electrode 51.

In some embodiments, since the light emitted by different sub-pixels 50 has different colors and the materials of the light-emitting layers 53 in different sub-pixels 50 are different, the sub-pixels 50 emitting light of different colors need to be manufactured in different steps. The light-emitting layers 53 include, but is not limited to, a red light-emitting layer, a green light-emitting layer, and a blue light-emitting layer. The specific sequence of forming the red light-emitting layer, the green light-emitting layer, and the blue light-emitting layer may be set according to the actual situation. For example, the red light-emitting layer is formed first, then the green light-emitting layer is formed, and finally the blue light-emitting layer is formed.

At block S330, the second functional layer 54 is deposited on a side of the light-emitting layer 53 away from the first functional layer 52.

At block S340, the cathode electrode 55 and an encapsulating layer 700 are deposited on a side of the second functional layer 54 away from the light-emitting layer 53.

In some embodiments, the material of the cathode electrode 55 may include, but not limited to, chromium, titanium, gold, silver, copper, aluminum, ITO, a combination thereof, or other suitable conductive materials.

The encapsulating layer 700 is deposited on a side of the cathode electrode 55 away from the second functional layer 54.

At block S350, a filling layer 800 is filled on a side of the encapsulating layer 700 away from the cathode electrode 55.

At block S360, a cover plate 900 is disposed on a side of the filling layer 800 away from the cathode electrode 55.

In some embodiments, the material of the cover plate 900 may be glass or thin film plastic.

In summary, the present disclosure provides the display panel 2 including the driving plate 10, the pixel defining layer 20, the cathode auxiliary layer 30, the first partition structure 40, the plurality of sub-pixels 50, and the second partition structure 60. The pixel defining layer 20 is disposed on the driving plate 10. The pixel defining layer 20 protrudes from the driving plate 10 and defines the pixel accommodating region 21. The cathode auxiliary layer 30 is disposed on the side of the pixel defining layer 20 away from the driving plate 10. The first partition structure 40 protrudes from the side of the cathode auxiliary layer 30 away from the pixel defining layer 20. Each of the plurality of sub-pixels 50 is at least partially disposed in the pixel accommodating region 21. Each of the sub-pixels 50 includes the anode electrode 51, the first functional layer 52, the light-emitting layer 53, the second functional layer 54, and the cathode electrode 55, which are arranged in a stack. The two adjacent sub-pixels 50 are separated from each other by the first partition structure 40. Two cathode electrodes 55 of the two adjacent sub-pixels 50 are electrically connected through the cathode auxiliary layer 30. The second partition structure 60 is connected to the pixel defining layer 20. The second partition structure 60 is configured to divide the first functional layer 52 into the plurality of functional segments separated from each other, to make each of the functional segments to be connected to one of or none of the cathode auxiliary layer 30 and the anode electrode 51. According to the above embodiments, the first functional layer 52 is divided into the plurality of functional segments separated from each other by the second partition structure 60. As a result, the plurality of functional segments do not conduct electricity continuously, thereby greatly reducing the risk of the cathode auxiliary layer 30 being electrically conductive to the anode electrode 51 through the first functional layer 52 and further leading to crosstalk short-circuit between the cathode electrode 55 and the anode electrode 51.

It should be noted that, the embodiments above are merely used to illustrate the technical solutions of the present disclosure, not to limit them. Although the present disclosure has been described in detail in conjunction with the embodiments above, those skilled in the art should understand that, the technical solutions described in the embodiments above may still be modified, or some or all of the technical features thereof may be equivalently replaced. These modifications or replacements do not cause the essence of the corresponding technical solutions to depart from the scope of the technical solutions in the embodiments of the present disclosure, and to be all covered within the scope of the claims and the description of the present disclosure. In particular, all the technical features mentioned in various embodiments may be combined in any way as long as there is no structural conflict. The present disclosure is not limited to the specific embodiments disclosed herein, but includes all technical solutions falling within the scope of the claims.

1. A display panel, comprising:
a driving plate;
a pixel defining layer, disposed on the driving plate, protruding from the driving plate, and defining a pixel accommodating region;
a cathode auxiliary layer, disposed on a side of the pixel defining layer away from the driving plate;
a first partition structure, protruding from a side of the cathode auxiliary layer away from the pixel defining layer;
a plurality of sub-pixels, wherein each of the sub-pixels is at least partially disposed in the pixel accommodating region, and comprises an anode electrode, a first functional layer, a light-emitting layer, a second functional layer, and a cathode electrode, which are arranged in a stack, two adjacent sub-pixels are separated from each other by the first partition structure, and cathode electrodes of the two adjacent sub-pixels are electrically connected through the cathode auxiliary layer; and
a second partition structure, connected to the pixel defining layer and configured to divide the first functional layer into a plurality of functional segments separated from each other, to make each of the functional segments to be connected to one of or none of the cathode auxiliary layer and the anode electrode.

2. The display panel according to claim 1, wherein in a separation direction of the two adjacent sub-pixels, a length of an orthographic projection of the first partition structure projected on the driving plate is smaller than a length of an orthographic projection of the cathode auxiliary layer projected on the driving plate.

3. The display panel according to claim 1, wherein the second partition structure comprises a first sub-partition structure disposed on a side of the anode electrode away from the driving plate, and the pixel defining layer is covered the first sub-partition structure.

4. The display panel according to claim 3, wherein the functional segments comprise a first functional segment located on a surface of the anode electrode away from the driving plate, and a thickness of the first functional segment is smaller than a thickness of the first sub-partition structure.

5. The display panel according to claim 1, wherein the second partition structure comprises a second sub-partition structure disposed on the side of the pixel defining layer away from the driving plate, and the cathode auxiliary layer is covered the second sub-partition structure.

6. The display panel according to claim 5, wherein the functional segments comprise a second functional segment located on a surface of the pixel defining layer away from the driving plate, and a thickness of the second functional segment is smaller than a thickness of the second sub-partition structure.

7. The display panel according to claim 1, wherein the second partition structure comprises a first sub-partition structure and a second sub-partition structure;
the first sub-partition structure is disposed on a side of the anode electrode away from the driving plate, and the pixel defining layer is covered the first sub-partition structure;
the second sub-partition structure is disposed on the side of the pixel defining layer away from the driving plate, and the cathode auxiliary layer is covered the second sub-partition structure.

8. The display panel according to claim 1, wherein the first partition structure comprises a protruding portion and a partition portion, the protruding portion is protrudingly disposed on the side of the cathode auxiliary layer away from the pixel defining layer, and the partition portion is disposed on a side of the protruding portion away from the cathode auxiliary layer;
in a separation direction of the two adjacent sub-pixels, a length of an orthographic projection of the partition portion projected on the driving plate is greater than a length of an orthographic projection of the protruding portion projected on the driving plate, and the length of the orthographic projection of the partition portion projected on the driving plate is smaller than a length of an orthographic projection of the cathode auxiliary layer projected on the driving plate.

9. A method for producing a display panel, comprising:
forming a second partition structure on a side of a pixel defining layer;
forming a first partition structure on a side of a cathode auxiliary layer away from a driving plate; and
depositing a first functional layer, a light-emitting layer, a second functional layer, and a cathode electrode on a side of an anode electrode away from the driving plate, wherein the second partition structure is configured to divide the first functional layer into a plurality of functional segments separated from each other, to make each of the functional segments to be connected to one of or none of the cathode auxiliary layer and the anode electrode.

10. The method according to claim 9, wherein the forming a second partition structure on a side of a pixel defining layer comprises:
disposing a metal layer and a first sub-partition structure source layer on the driving plate;
etching the metal layer and the first sub-partition structure source layer;
forming a pixel defining layer on the driving plate;
defining first openings on the pixel defining layer, wherein the first openings are separated from each other; and
etching the first sub-partition structure source layer through the first openings.

11. The method according to claim 10, wherein the forming a second partition structure on a side of a pixel defining layer further comprises:
disposing a second sub-partition structure source layer and a cathode auxiliary layer source layer on a side of the pixel defining layer away from the driving plate; and
etching the cathode auxiliary layer source layer and the second sub-partition structure source layer.

12. The method according to claim 9, wherein the forming a second partition structure on a side of a pixel defining layer comprises:
disposing a metal layer on the driving plate;
etching the metal layer;
forming a pixel defining layer on the driving plate;
defining first openings on the pixel defining layer, wherein the first openings are separated from each other;
disposing a second sub-partition structure source layer and a cathode auxiliary layer source layer on a side of the pixel defining layer away from the driving plate; and
etching the cathode auxiliary layer source layer and the second sub-partition structure source layer.

13. The method according to claim 9, wherein the depositing a first functional layer, a light-emitting layer, a second functional layer, and a cathode electrode on a side of an anode electrode away from the driving plate comprises:
depositing the first functional layer on the side of the anode electrode away from the driving plate;
depositing the light-emitting layer on a side of the first functional layer away from the anode electrode;
depositing the second functional layer on a side of the light-emitting layer away from the first functional layer; and
depositing the cathode electrode on a side of the second functional layer away from the light-emitting layer.

14. The method according to claim 13, further comprising:
depositing an encapsulating layer on a side of the cathode electrode away from the second functional layer;
filling a filling layer on a side of the encapsulating layer away from the cathode electrode; and
disposing a cover plate on a side of the filling layer away from the cathode electrode.

15. A display device, comprising a display panel, wherein the display panel comprises:
a driving plate;
a pixel defining layer, disposed on the driving plate, protruding from the driving plate, and defining a pixel accommodating region;
a cathode auxiliary layer, disposed on a side of the pixel defining layer away from the driving plate;
a first partition structure, protruding from a side of the cathode auxiliary layer away from the pixel defining layer;
a plurality of sub-pixels, wherein each of the sub-pixels is at least partially disposed in the pixel accommodating region, and comprises an anode electrode, a first functional layer, a light-emitting layer, a second functional layer, and a cathode electrode, which are arranged in a stack, two adjacent sub-pixels are separated from each other by the first partition structure, and cathode electrodes of the two adjacent sub-pixels are electrically connected through the cathode auxiliary layer; and
a second partition structure, connected to the pixel defining layer and configured to divide the first functional layer into a plurality of functional segments separated from each other, to make each of the functional segments to be connected to one of or none of the cathode auxiliary layer and the anode electrode.

16. The display device according to claim 15, wherein in a separation direction of the two adjacent sub-pixels, a length of an orthographic projection of the first partition structure projected on the driving plate is smaller than a length of an orthographic projection of the cathode auxiliary layer projected on the driving plate.

17. The display device according to claim 15, wherein the second partition structure comprises a first sub-partition structure disposed on a side of the anode electrode away from the driving plate, and the pixel defining layer is covered the first sub-partition structure.

18. The display device according to claim 17, wherein the functional segments comprise a first functional segment located on a surface of the anode electrode away from the driving plate, and a thickness of the first functional segment is smaller than a thickness of the first sub-partition structure.

19. The display device according to claim 15, wherein the second partition structure comprises a second sub-partition structure disposed on the side of the pixel defining layer away from the driving plate, and the cathode auxiliary layer is covered the second sub-partition structure.

20. The display device according to claim 15, wherein the first partition structure comprises a protruding portion and a partition portion, the protruding portion is protrudingly disposed on the side of the cathode auxiliary layer away from the pixel defining layer, and the partition portion is disposed on a side of the protruding portion away from the cathode auxiliary layer;
in a separation direction of the two adjacent sub-pixels, a length of an orthographic projection of the partition portion projected on the driving plate is greater than a length of an orthographic projection of the protruding portion projected on the driving plate, and the length of the orthographic projection of the partition portion projected on the driving plate is smaller than a length of an orthographic projection of the cathode auxiliary layer projected on the driving plate.
